(19) United States
(12) Patent Application Publication
(10) Pub. No.: US 2026/0143876 A1
(43) Pub. Date: May 21, 2026

(54) STRESS MITIGATION STRUCTURES IN LEAD FRAMES FOR LIGHT-EMITTING DIODES

(71) Applicant: CreeLED, Inc., Durham, NC (US)

(72) Inventors: Seth Joseph Balkey, Pittsboro, NC (US); Eric William Knowles, Cary, NC (US); William Sheldon Taylor, Durham, NC (US)

(21) Appl. No.: 19/381,311

(22) Filed: Nov. 6, 2025

Related U.S. Application Data
(60) Provisional application No. 63/722,119, filed on Nov. 19, 2024.

(51) Int. Cl. H10H 20/857; H10H 20/85

(52) U.S. Cl. CPC H10H 20/857; H10H 20/8506

(57) ABSTRACT

Light-emitting diode (LED) devices and more particularly LED devices with stress mitigation structures in lead frames for LED packages and related devices are disclosed. Stress mitigation structures include one or more leads that form floating bond pads for receiving at least one contact of a flip-chip LED. The floating bond pads are configured to be decoupled from bonding regions for corresponding LED packages. Leads that form floating bond pads are electrically coupled to other leads by way of electrical connectors with increased elasticity relative to the lead frame. During operation, transfer of stress associated with coefficient of thermal expansion differences between LED packages and associated mounting boards is reduced.

### RELATED APPLICATIONS

This application claims the benefit of provisional patent application Ser. No. 63/722,119, filed November 19, 2024, the disclosure of which is hereby incorporated herein by reference in its entirety.

### FIELD OF THE DISCLOSURE

The present disclosure relates to light-emitting diode (LED) devices, and more particularly to LED devices with stress mitigation structures in lead frames for LED packages and related devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

LED packages are solid-state devices that incorporate one or more LED chips into a packaged device. LED packages have been developed that may provide mechanical support, electrical connections, and encapsulation for LED chips. Lumiphoric materials, such as phosphors, may also be arranged in close proximity to LED emitters to convert portions of light emissions to different wavelengths.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to LED devices with stress mitigation structures in lead frames for LED packages and related devices. Stress mitigation structures include one or more leads that form floating bond pads for receiving at least one contact of a flip-chip LED. The floating bond pads are configured to be decoupled from bonding regions for corresponding LED packages. Leads that form floating bond pads are electrically coupled to other leads by way of electrical connectors with increased elasticity relative to the lead frame. During operation, transfer of stress associated with coefficient of thermal expansion differences between LED packages and associated mounting boards is reduced.

In one aspect, an LED package comprises: a housing forming a recess with a recess floor; a lead frame structure extending through the housing, the lead frame structure comprising a first lead forming an anode connection for the LED package, a second lead forming a cathode connection for the LED package, and a third lead; a first LED chip flip-chip bonded to the third lead; and at least one electrical connector bonded to the first lead and the third lead, the at least one electrical connector bonded to a portion of the third lead that is laterally spaced from the first LED chip. In certain embodiments, the at least one electrical connector comprises a plurality of wire bonds electrically coupled between the first lead and the third lead. In certain embodiments, the third lead extends to a bottom of the housing opposite the recess. The LED package may further comprise: a fourth lead and a fifth lead of the lead frame structure, wherein the first LED chip is flip-chip bonded to the third lead and the fifth lead; and a second LED chip flip-chip bonded to the fourth lead and the fifth lead; and one or more additional electrical connectors bonded to the fourth lead and the second lead.

In certain embodiments, the first LED chip is flip-chip bonded to the third lead and the second lead. The LED package may further comprise: a fourth lead of the lead frame structure, wherein the first LED chip is flip-chip bonded to the third lead and the fourth lead; and one or more additional electrical connectors bonded to the fourth lead and the second lead. In certain embodiments, a portion of the housing covers a bottom of the third lead opposite the recess. In certain embodiments, the at least one electrical connector comprises electrically conductive particles in a binder. The LED package may further comprise light-reflective particles in the binder.

In another aspect, an LED package comprises: a mounting board comprising an anode mounting pad and a cathode mounting pad; and at least one LED package mounted to the anode mounting pad and the cathode mounting pad, the at least one LED package comprising: a housing forming a recess with a recess floor; a lead frame structure extending through the housing, the lead frame structure comprising a first lead bonded to the anode mounting pad, a second lead bonded to the cathode mounting pad, and a third lead; a first LED chip flip-chip bonded to the third lead; and at least one electrical connector bonded to the first lead and the third lead, the at least one electrical connector bonded to a portion of the third lead that is laterally spaced from the first LED chip. In certain embodiments, the mounting board comprises a printed circuit board. In certain embodiments, the third lead extends to a bottom of the housing, and the LED device is devoid of bonding materials between the third lead and the mounting board. In certain embodiments, the at least one electrical connector comprises a plurality of wire bonds electrically coupled between the first lead and the third lead. The LED device may further comprise: a fourth lead and a fifth lead of the lead frame structure, wherein the first LED chip is flip-chip bonded to the third lead and the fifth lead; and a second LED chip flip-chip bonded to the fourth lead and the fifth lead; and one or more additional electrical connectors bonded to the fourth lead and the second lead. The LED device may further comprise a thermal mounting pad of the mounting board, wherein the fifth lead is bonded to the thermal mounting pad. In certain embodiments, the fifth lead extends to a bottom of the housing, and the LED device is devoid of bonding materials between the fifth lead and the mounting board. In certain embodiments, the first LED chip is flip-chip bonded to the third lead and the second lead. The LED device may further comprise: a fourth lead of the lead frame structure, wherein the first LED chip is flip-chip bonded to the third lead and the fourth lead; and one or more additional electrical connectors bonded to the fourth lead and the second lead. In certain embodiments, the LED device is devoid of bonding materials between the mounting board and the third and fourth leads. In certain embodiments, a portion of the housing covers a bottom of the third lead opposite the recess. In certain embodiments, the at least one electrical connector comprises electrically conductive particles in a binder.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top perspective view of a light-emitting diode (LED) package with a lead frame structure according to principles of the present disclosure.

FIG. 1B is a top perspective view of the LED package of FIG. 1A with LED chips mounted thereon.

FIG. 1C is a bottom view of the LED package of FIG. 1A. As illustrated, portions of each of the leads may be accessible from the bottom side of the housing.

FIG. 1D is a cross-sectional view taken along the sectional line 1D-1D of the LED package of FIG. 1B.

FIG. 2A is a cross-sectional view of an LED device that includes the LED package of FIGS. 1A to 1D mounted and electrically coupled to a mounting board.

FIG. 2B is a cross-sectional view of the LED device of FIG. 2A with an alternative configuration of the mounting board.

FIG. 3 is a cross-sectional view of an LED package similar to the LED package of FIGS. 1A to 1D for embodiments where a single floating pad is formed the lead frame structure.

FIG. 4 is a cross-sectional view of an LED device that includes the LED package of FIG. 3.

FIG. 5 is a cross-sectional view of an LED package similar to the LED package of FIGS. 1A to 1D for embodiments without the thermal pad formed by the lead of FIGS. 1A to 1D.

FIG. 6 is a cross-sectional view of an LED device that includes the LED package of FIG. 5.

FIG. 7A is a cross-sectional view of an LED package similar to the LED package of FIGS. 1A to 1D for embodiments where portions of the housing cover the leads on a bottom side of the housing.

FIG. 7B is a bottom view of the LED package of FIG. 7A.

FIG. 8 is a cross-sectional view of an LED package similar to the LED package of FIG. 3 for embodiments where portions of the housing cover the lead on a bottom side of the housing.

FIG. 9A is a top perspective view of an LED package similar to the LED package of FIGS. 1A to 1D for embodiments with an alternative configuration for the electrical connectors.

FIG. 9B is a cross-sectional view of a portion of the LED package of FIG. 9A illustrating an embodiment for the material of the electrical connectors.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to LED devices with stress mitigation structures in lead frames for LED packages and related devices. Stress mitigation structures include one or more leads that form floating bond pads for receiving at least one contact of a flip-chip LED. The floating bond pads are configured to be decoupled from bonding regions for corresponding LED packages. Leads that form floating bond pads are electrically coupled to other leads by way of electrical connectors with increased elasticity relative to the lead frame. During operation, transfer of stress associated with coefficient of thermal expansion differences between LED packages and associated mounting boards is reduced.

Before delving into specific details of various aspects of the present disclosure, an overview of various elements that may be included in exemplary LED packages of the present disclosure is provided for context. An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements may also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In), such as gallium nitride (GaN), aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds.

The active LED structure may be grown on a growth substrate that may include many materials, such as sapphire, silicon carbide (SiC), aluminum nitride (AlN), and GaN. Different embodiments of the active LED structure may emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm). The UV spectrum is typically divided into three wavelength range categories denotated with letters A, B, and C.

An LED chip may also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

According to aspects of the present disclosure, LED packages may include one or more elements, such as lumiphoric materials, encapsulants, light-altering materials, lenses, and electrical contacts, among others, that are provided with one or more LED chips. In certain aspects, an LED package may include a support member, such as a lead frame structure, which may also be referred to as a lead frame. Light-altering materials may be arranged within LED packages to reflect or otherwise redirect light from the one or more LED chips in a desired emission direction or pattern.

As used herein, light-altering materials may include many different materials including light-reflective materials that reflect or redirect light, light- absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. In certain aspects, the particles may have an index of refraction that is configured to refract light emissions in a desired direction. In certain aspects, light-reflective particles may also be referred to as light-scattering particles. For light-absorbing materials, the light-altering material may include at least one of carbon, silicon, metal, and organic particles suspended in a binder, such as silicone or epoxy. Such organic particles may include various pigments, dyes, and/or absorptive additives. Thixotropic materials may include one or more of glass fillers, fumed silica and/or fused silica. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast. In certain embodiments, the light-altering material includes both light-reflective material and light-absorbing material suspended in a binder. As used herein, a layer or coating of one or more light-altering materials may be referred to as a light-altering coating. In certain embodiments, a light-altering material or coating may be devoid of lumiphoric materials.

The present disclosure may be useful for LED chips having a variety of geometries, and in particular for flip-chip LED structures. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections.

In certain embodiments, a lateral geometry LED chip may embody a flip-chip LED that is mounted on a surface of an LED package such that the anode and cathode connections are on a face of the active LED structure that is adjacent the mounting surface. In this configuration, a lead frame structure may be incorporated within the LED package for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

In certain embodiments, aspects of the present disclosure relate to arrangements of lead frame structures in LED packages, and more particularly to LED packages with lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

Current high-efficiency mid-power LED packages typically employ lateral geometry LED chips in a lead frame package for cost purposes. Lateral geometry orientations with topside wire bond contacts and polymer-based substrate attach materials provide simple, efficient LED package structures. One approach to increase the efficiency in such LED package structures is to increase an active light-emitting area by increasing a number of LED chips in the LED package.

Additionally, different orientations of LED chips, such as flip-chip LEDs may be used while maintaining the approach of increasing the active light-emitting area of the package. While flip-chip orientations of LED chips typically provide a more efficient LED architecture with higher lumen per watt operation, the LED chips must make direct electrical contact with the lead frame structure. This presents a number of challenges such as a more complex lead frame structure for the LED to bond directly to while maintaining the current forward voltage. Additionally, the use of flip-chip LEDs with direct attachments to the lead frame structure may create higher stress between the LED package and external mounting boards, such as a printed circuit board, due to the different coefficients of thermal expansion between the lead frame structure and the external mounting board. Exemplary mounting boards for LED packages may include one or more materials, such as Al, copper (Cu), glass-reinforced epoxy laminate materials (e.g., FR4), and the like that contribute to differences in coefficients of thermal expansion.

According to aspects of the present disclosure, LED packages with one or more flip-chip LEDs on lead frame structures are provided. In certain aspects, a single flip-chip LED or multiple flip-chip LEDs, such as 2 or more, or 3 or more, or 6 or more, may be provided in a single LED package with a lead frame structure. The various leads of the lead frame structures may be arranged to receive and electrically connect flip-chip LEDs in series, parallel, and combinations thereof. In certain embodiments, such LED packages may have various footprints, ranging from smaller sizes up to 5 mm x 5 mm or above while maintaining suitable forward driving voltages.

According to aspects of the present disclosure, LED packages are disclosed that include lead frame structures with stress relief features in the form of floating bonding pads of the lead frame that are decoupled from external bonding surfaces. One or more contacts of LED chips may be flip-chip bonded to at least one floating bonding pad. The at least one floating bond pad may be electrically connected to another portion of the lead frame that is bonded to the external surface by way of a more flexible electrical connection, such as a wire bond or the like. Accordingly, stress transfer from the mounting board may be buffered from the flip-chip bonding interfaces between the LED chip and the lead frame, thereby increasing operating lifetime and reliability of the LED package.

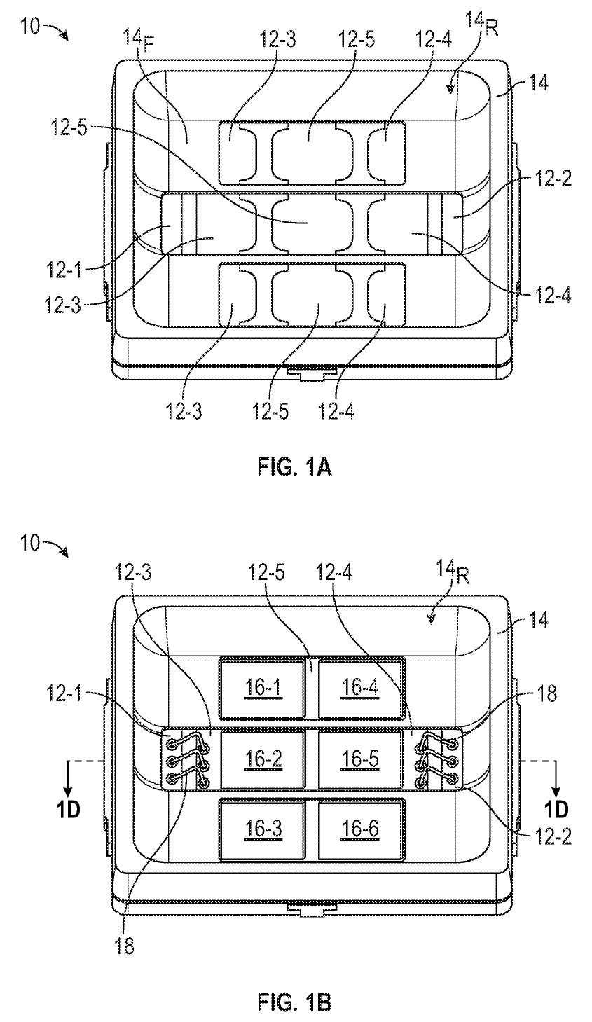

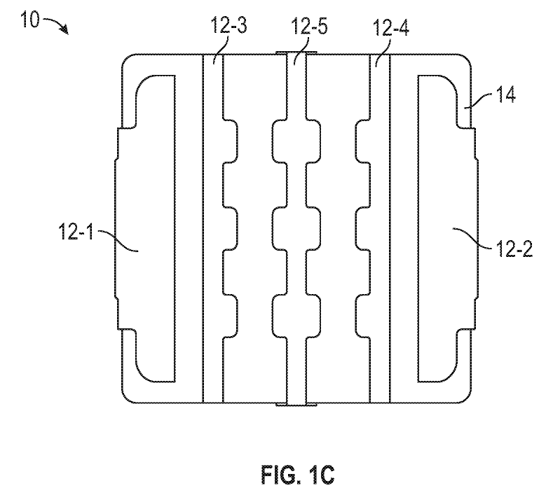

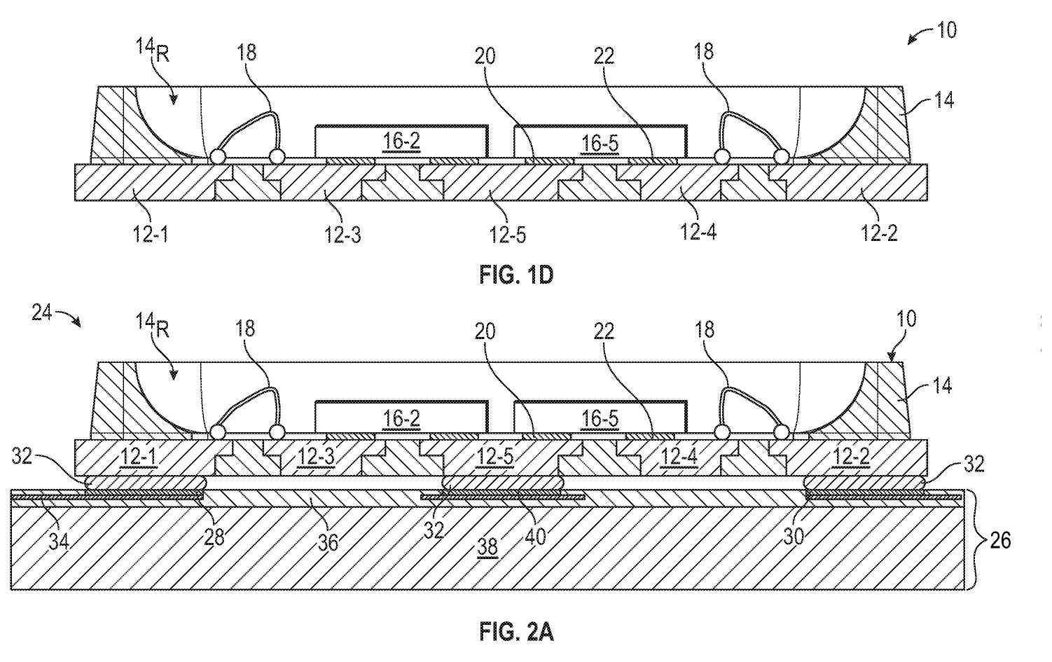

FIG. 1A is a top perspective view of an LED package 10 with a lead frame structure according to principles of the present disclosure. The lead frame structure is formed by a number of leads 12-1 to 12-5 that are at least partially encased by a housing 14. The housing forms a recess 14_{R} and a recess floor 14_{F} where portions of the leads 12-1 to 12-5 are exposed. In the example of FIG. 1A, each of the leads 12-3 to 12-5 form continuous structures and have portions thereof covered by portions of the housing 14 along the recess floor 14_{F} to define LED chip mounting areas or die attach pads. Portions of the leads 12-1 to 12-2 extend out of the housing 14 for making contact with an external mounting board. As will be described later in greater detail, at least the leads 12-3 and 12-4 form floating bonding pads for receiving one or more flip-chip LEDs in that the leads 12-3 and 12-4 are not directly bonded to traces of the external mounting board.

FIG. 1B is a top perspective view of the LED package 10 of FIG. 1A with LED chips 16-1 to 16-6 mounted thereon. The LED chips 16-1 to 16-3 are flip-chip mounted to the leads 12-3 and 12-5, and electrical connections between the lead 12-3 and the lead 12-1 are provided by way of one or more electrical connectors 18, such as wire bonds, that form flexible and stress-absorbing electrical connections. In a similar manner, the LED chips 16-4 to 16-6 are flip-chip mounted to the leads 12-4 and 12-5, and electrical connections between the lead 12-4 and the lead 12-2 are also provided by way of one or more electrical connectors 18.

FIG. 1C is a bottom view of the LED package 10 of FIG. 1A. As illustrated, portions of each of the leads 12-1 to 12-5 may be accessible from the bottom side of the housing 14. When mounted to a mounting board, the leads 12-1 and 12-2 form respective anode and cathode connections for the LED package 10, while at least the leads 12-3 and 12-4 are configured to be not directly bonded to the mounting board. In certain embodiments, the lead 12-5 may form a neutral and/or a thermal pad for the LED package 10.

FIG. 1D is a cross-sectional view taken along the sectional line 1D-1D of the LED package 10 of FIG. 1B. As illustrated, the LED chips 16-2, 16-5 are flip-chip mounted such that anode contacts 20 and cathode contacts 22 are mounted and electrically coupled to various pairs of the leads 12-3 to 12-5. For example, the anode contact 20 of the LED chip 16-5 is bonded and electrically coupled to the lead 12-5, and the cathode contact 22 of the LED chip 16-5 is bonded and electrically coupled to the lead 12-4.

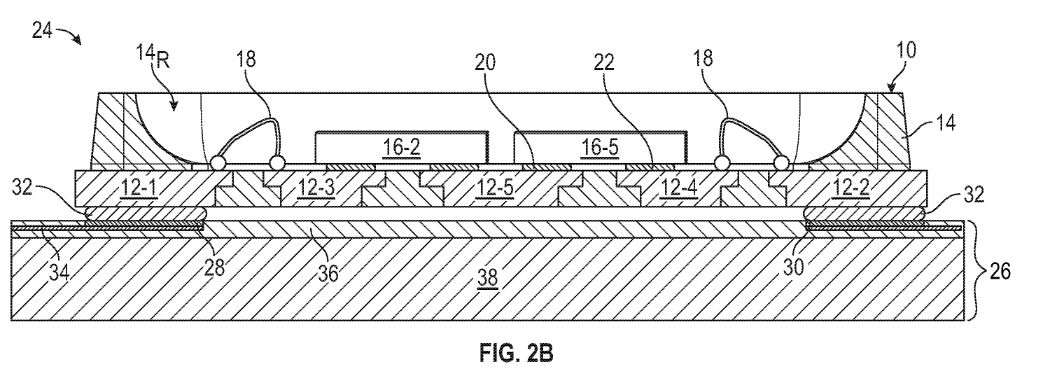

FIG. 2A is a cross-sectional view of an LED device 24 that includes the LED package 10 of FIGS. 1A to 1D mounted and electrically coupled to a mounting board 26. The mounting board 26 may embody a printed circuit board with anode and cathode mounting pads 28, 30 positioned for receiving the leads 12-1 and 12-2. Accordingly, the anode mounting pad 28 is electrically coupled to the lead 12-1 that forms an anode connection for the LED package 10, while the cathode mounting pad 30 is electrically coupled to the lead 12-2 that forms a cathode connection for the LED package 10. A bonding material 32, such as a solder or the like, may be used to facilitate electrical coupling and bonding. The anode and cathode mounting pads 28, 30 may be electrically coupled to other elements of the mounting board 26 by way of electrical traces 34 that extend on or within an insulating layer 36. The mounting board 26 may further comprise a base material 38, such as a thermally conductive metal. In certain embodiments, the lead 12-5 may be mounted and thermally coupled to a corresponding thermal mounting pad 40 of the mounting board 26. In certain embodiments, the thermal mounting pad 40 is not electrically isolated.

As further illustrated in FIG. 2A, the leads 12-3 and 12-4 essentially form floating pads or leads that are not mechanically anchored to the mounting board 26. While portions of the leads 12-3 and 12-4 extend to a bottom surface of the housing 14, the leads 12-3 and 12-4 remain spaced from the mounting board 26 without any bonding materials therebetween. During operation, coefficients of thermal expansion differences between portions of the LED package 10, such as the leads 12-1 and 12-2, and various materials of the mounting board 26 may introduce stress that could comprise the integrity of the bonding material 32 and the bonding integrity of the LED chips 16-2, 16-5 in conventional LED packages. However, providing the leads 12-3 and 12-4 as floating pads with respect to the mounting board 26, transmitted stress to the LED chips 16-2, 16-5 may be reduced. At certain stress levels, transmitted stress may be absorbed by the flexible nature of the electrical connectors 18, thereby relieving excessive strain on the LED chips 16-2, 16-5. As illustrated, the electrical connectors 18 are bonded, or directly bonded, to the lead 12-3 and the lead 12-4 at positions laterally spaced from the LED chips 16-2, 16-5. With reference back to FIG. 1B, multiple electrical connectors 18 may be bonded between respective pairs of the leads (i.e., between the leads 12-1 and 12-3, and between the leads 12-4 and 12-2). This may advantageously provide additional stress absorbing connections to effectively spread and absorb stress across multiple electrical connectors 18, while also facilitating increased current handling.

FIG. 2B is a cross-sectional view of the LED device 24 of FIG. 2A with an alternative configuration of the mounting board 26. In FIG. 2B, the thermal mounting pad 40 of FIG. 2A is omitted from the mounting board 26. As such, the leads 12-3, 12-4, and 12-5 each form floating pads with respect to the mounting board 26.

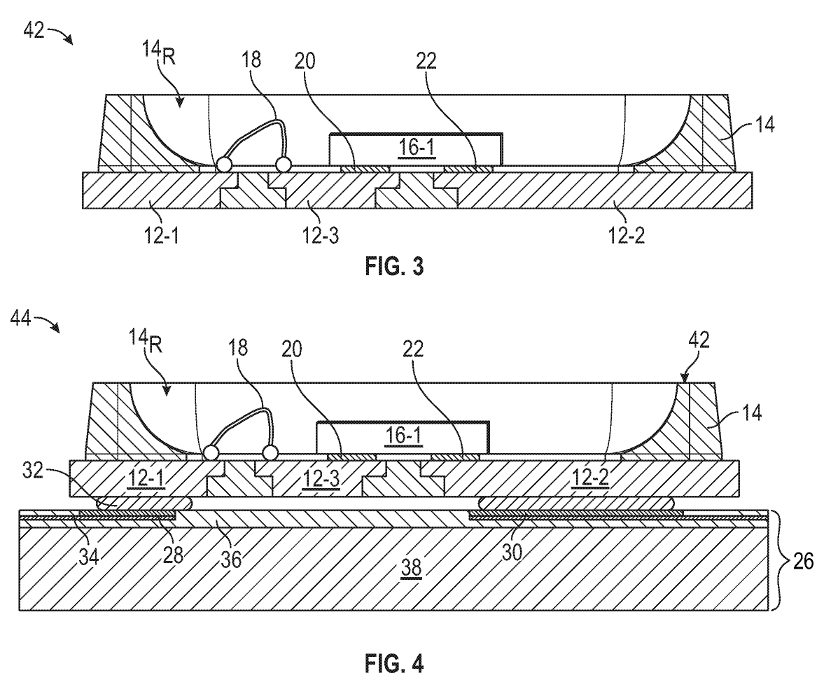

FIG. 3 is a cross-sectional view of an LED package 42 similar to the LED package 10 of FIGS. 1A to 1D for embodiments where a single floating pad is formed by the lead 12-3. As illustrated, the LED chip 16-1 of the LED package 42 is flip-chip mounted to the lead 12-3 and the lead 12-2, while electrical connectors 18 provide electrically conductive pathways and stress absorbing features between the lead 12-1 and the lead 12-3.

FIG. 4 is a cross-sectional view of an LED device 44 that includes the LED package 42 of FIG. 3. The LED package 42 is mounted and electrically coupled to the mounting board 26 in a similar manner as described above with respect to FIG. 2. In this example, the cathode contact 22 is bonded to the lead 12-2, which is in turn bonded to the cathode mounting pad 30 of the mounting board 26. As such, some coefficient of thermal expansion stress may transfer to the LED chip 16-1. However, the anode contact 20 is bonded to the lead 12-3, which is mechanically floating with respect to the mounting board 26. Accordingly, other coefficient of thermal expansion stress following the pathway of the lead 12-1 may be effectively absorbed by the flexible nature of the electrical connectors 18. In certain applications, a single mechanically floating lead (e.g., 12-3) may be sufficient to mitigate stress while also sufficiently anchoring the LED chip 16-1 and the LED package 42 to the mounting board 26.

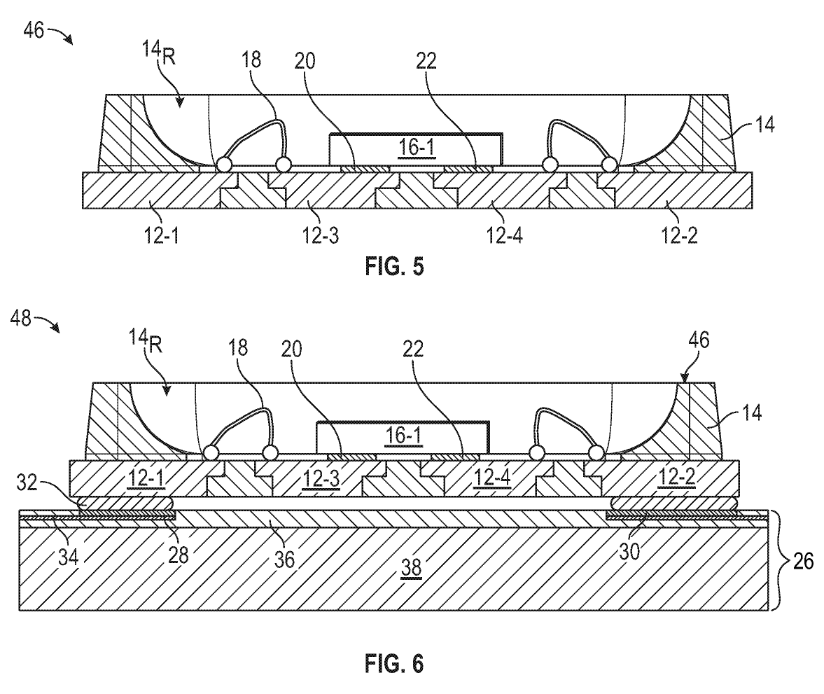

FIG. 5 is a cross-sectional view of an LED package 46 similar to the LED package 10 of FIGS. 1A to 1D for embodiments without the thermal pad formed by the lead 12-5 of FIGS. 1A to 1D. In FIG. 5, the LED package 46 includes two floating pads formed by the leads 12-3 and 12-4. As illustrated, the LED chip 16-1 is flip-chip mounted to the lead 12-3 and the lead 12-4. Electrical connectors 18 provide electrically conductive pathways and stress absorbing features between the lead 12-1 and the lead 12-3, and between the lead 12-4 and the lead 12-2.

FIG. 6 is a cross-sectional view of an LED device 48 that includes the LED package 46 of FIG. 5. The LED package 46 is mounted and electrically coupled to the mounting board 26 in a similar manner as described above with respect to FIG. 2. As illustrated, both leads 12-3 and 12-4 remain floating with respect to the mounting board 26. Since the LED chip 16-1 is flip-chip bonded to the leads 12-3 and 12-4, coefficient of thermal expansion stress propagating through the lead 12-1 and the lead 12-2 may be absorbed by the electrical connectors 18.

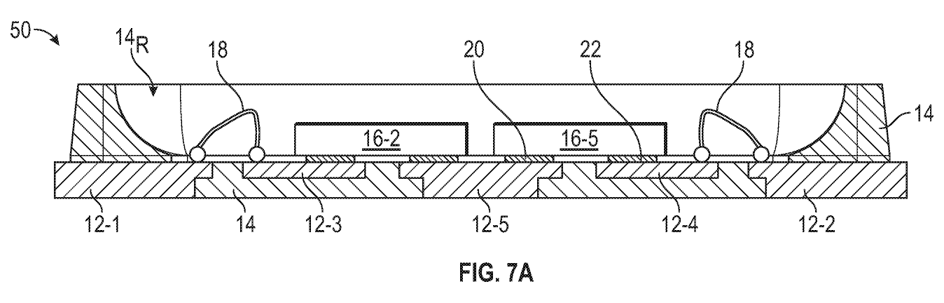

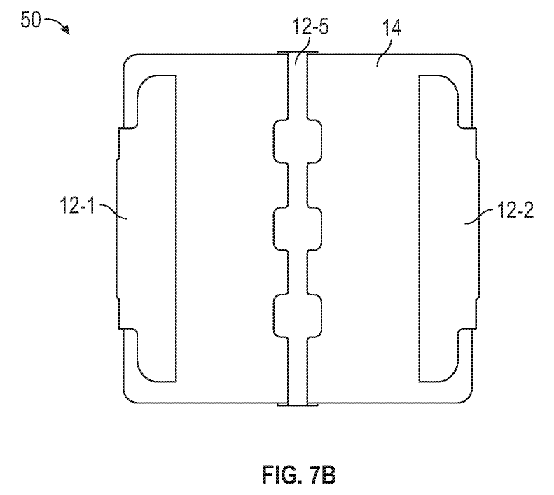

FIG. 7A is a cross-sectional view of an LED package 50 similar to the LED package 10 of FIGS. 1A to 1D for embodiments where portions of the housing 14 cover the leads 12-3 and 12-4 on a bottom side of the housing 14. As illustrated, the leads 12-3 and 12-4 are formed with reduced thickness within the housing 14 relative to the leads 12-1, 12-2, and 12-5. Accordingly, the housing 14 may be molded about the lead frame structure in a manner that covers bottoms of the leads 12-3 and 12-4 opposite the recess 14_{R}, effectively burying them within the housing 14. FIG. 7B is a bottom view of the LED package 50 of FIG. 7A. As illustrated, the leads 12-3 and 12-4 visible in FIG. 7A are not visible from the bottom view. Accordingly, when the LED package 50 is mounted to a mounting board, portions of the housing 14 effectively ensure the leads 12-3 and 12-4 are not inadvertently bonded to the mounting board. This ensures the floating nature of the leads 12-3 and 12-4 for directing stress through the leads 12-1 and 12-2 for absorption at the electrical connectors 18.

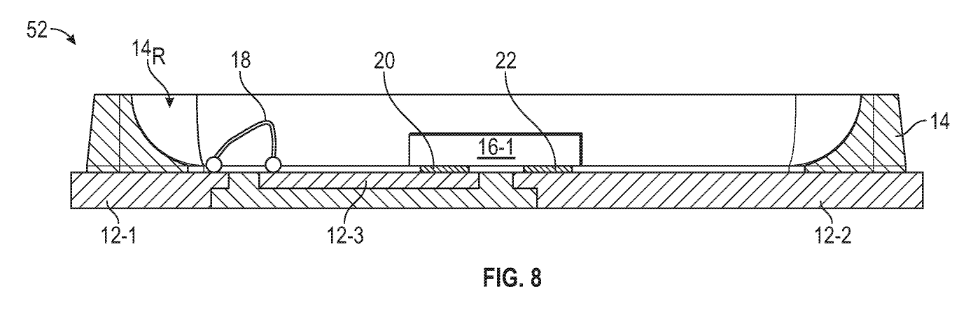

FIG. 8 is a cross-sectional view of an LED package 52 similar to the LED package 42 of FIG. 3 for embodiments where portions of the housing 14 cover the lead 12-3 on a bottom side of the housing 14. In a similar manner as described above with respect to FIGS. 7A and 7B, the lead 12-3 is formed with reduced thickness within the housing 14 relative to the leads 12-1 and 12-2. Accordingly, the housing 14 may be molded about the lead frame structure in a manner that covers a bottom of the lead 12-3 opposite the recess 14_{R}, effectively burying it within the housing 14.

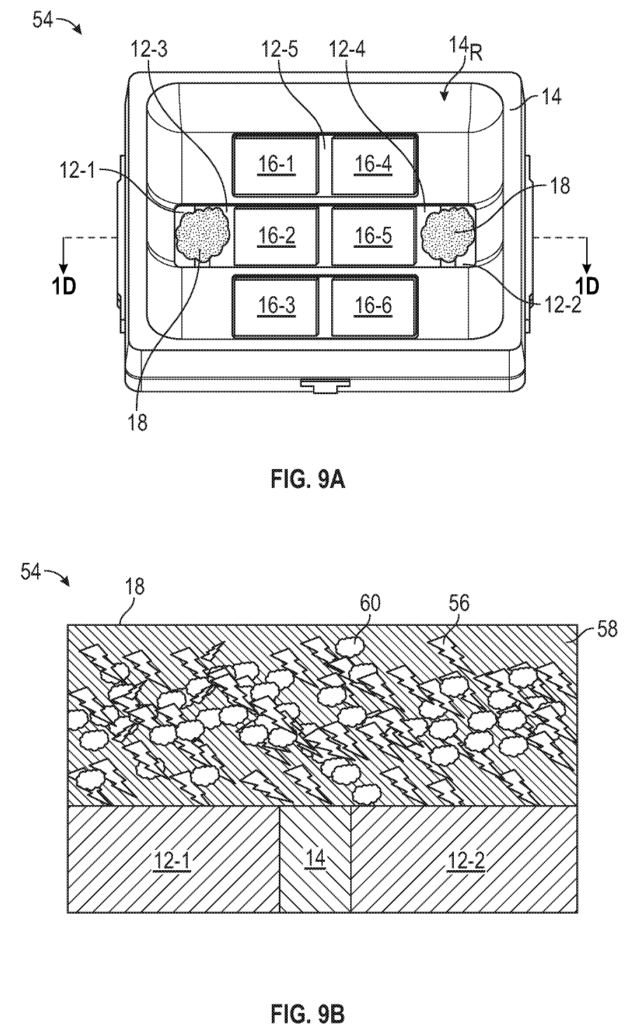

FIG. 9A is a top perspective view of an LED package 54 similar to the LED package 10 of FIGS. 1A to 1D for embodiments with an alternative configuration for the electrical connectors 18. Instead of wire bonds as described above, the electrical connectors 18 may form a flexible and conductive material that is placed, dispensed, or otherwise formed on the lead frame structure. The material for the electrical connectors 18 is selected to have suitable electrical conductivity while maintaining suitable elasticity during operation for stress absorption.

FIG. 9B is a cross-sectional view of a portion of the LED package 54 of FIG. 9A illustrating an embodiment for the material of the electrical connectors 18. The electrical connector 18 may include electrically conductive materials as particles 56 that are suspended within a host material or binder 58. The electrically conductive particles 56 are formed with a high enough density for forming suitable electrically conductive pathways through the binder 58 to electrically connect the leads 12-1 and 12-2. The binder 58 may be formed of a material, such as a polymer, that provides suitable elasticity for stress relief. In certain embodiments, light-reflective particles 60 may be added to the binder 58 to reduce light absorption. By way of example, the electrically conductive particles 56 may comprise silver (Ag), the light-reflective particles 60 may comprise TiO₂, and the binder 58 may comprise silicone in certain embodiments.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a housing forming a recess with a recess floor;
a lead frame structure extending through the housing, the lead frame structure comprising a first lead forming an anode connection for the LED package, a second lead forming a cathode connection for the LED package, and a third lead;
a first LED chip flip-chip bonded to the third lead; and
at least one electrical connector bonded to the first lead and the third lead, the at least one electrical connector bonded to a portion of the third lead that is laterally spaced from the first LED chip.

2. The LED package of claim 1, wherein the at least one electrical connector comprises a plurality of wire bonds electrically coupled between the first lead and the third lead.

3. The LED package of claim 1, wherein the third lead extends to a bottom of the housing opposite the recess.

4. The LED package of claim 1, further comprising:
a fourth lead and a fifth lead of the lead frame structure, wherein the first LED chip is flip-chip bonded to the third lead and the fifth lead; and
a second LED chip flip-chip bonded to the fourth lead and the fifth lead; and
one or more additional electrical connectors bonded to the fourth lead and the second lead.

5. The LED package of claim 1, wherein the first LED chip is flip-chip bonded to the third lead and the second lead.

6. The LED package of claim 1, further comprising:
a fourth lead of the lead frame structure, wherein the first LED chip is flip-chip bonded to the third lead and the fourth lead; and
one or more additional electrical connectors bonded to the fourth lead and the second lead.

7. The LED package of claim 1, wherein a portion of the housing covers a bottom of the third lead opposite the recess.

8. The LED package of claim 1, wherein the at least one electrical connector comprises electrically conductive particles in a binder.

9. The LED package of claim 8, further comprising light-reflective particles in the binder.

10. A light-emitting diode (LED) device comprising:
a mounting board comprising an anode mounting pad and a cathode mounting pad; and
at least one LED package mounted to the anode mounting pad and the cathode mounting pad, the at least one LED package comprising:
a housing forming a recess with a recess floor;
a lead frame structure extending through the housing, the lead frame structure comprising a first lead bonded to the anode mounting pad, a second lead bonded to the cathode mounting pad, and a third lead;
a first LED chip flip-chip bonded to the third lead; and
at least one electrical connector bonded to the first lead and the third lead, the at least one electrical connector bonded to a portion of the third lead that is laterally spaced from the first LED chip.

11. The LED device of claim 10, wherein the mounting board comprises a printed circuit board.

12. The LED device of claim 10, wherein the third lead extends to a bottom of the housing, and the LED device is devoid of bonding materials between the third lead and the mounting board.

13. The LED device of claim 10, wherein the at least one electrical connector comprises a plurality of wire bonds electrically coupled between the first lead and the third lead.

14. The LED device of claim 10, further comprising:
a fourth lead and a fifth lead of the lead frame structure, wherein the first LED chip is flip-chip bonded to the third lead and the fifth lead; and
a second LED chip flip-chip bonded to the fourth lead and the fifth lead; and
one or more additional electrical connectors bonded to the fourth lead and the second lead.

15. The LED device of claim 14, further comprising a thermal mounting pad of the mounting board, wherein the fifth lead is bonded to the thermal mounting pad.

16. The LED device of claim 14, wherein the fifth lead extends to a bottom of the housing, and the LED device is devoid of bonding materials between the fifth lead and the mounting board.

17. The LED device of claim 10, wherein the first LED chip is flip-chip bonded to the third lead and the second lead.

18. The LED device of claim 10, further comprising:
a fourth lead of the lead frame structure, wherein the first LED chip is flip-chip bonded to the third lead and the fourth lead; and
one or more additional electrical connectors bonded to the fourth lead and the second lead.

19. The LED device of claim 18, wherein the LED device is devoid of bonding materials between the mounting board and the third and fourth leads.

20. The LED device of claim 10, wherein a portion of the housing covers a bottom of the third lead opposite the recess.

21. The LED device of claim 10, wherein the at least one electrical connector comprises electrically conductive particles in a binder.
